(19) United States
(12) Patent Application Publication
(10) Pub. No.: US 2025/0234692 A1
(43) Pub. Date: Jul. 17, 2025

(54) DISPLAY PANEL, METHOD FOR MANUFACTURING SAME, AND DISPLAY DEVICE

(71) Applicant: BOE Technology Group Co., Ltd., Beijing (CN)

(72) Inventors: Ying CUI, Beijing (CN); Donghui YU, Beijing (CN); Cheng XU, Beijing (CN); Dandan ZHOU, Beijing (CN)

(73) Assignee: BOE Technology Group Co., Ltd., Beijing (CN)

(21) Appl. No.: 18/682,936

(22) PCT Filed: Mar. 31, 2023
(86) PCT No.: PCT/CN2023/085706

§ 371 Date: Feb. 12, 2024

(51) Int. Cl. H10H 29/851; H10H 29/01; H10H 29/80; H10H 29/856

(52) U.S. Cl. CPC H10H 29/8514; H10H 29/0361; H10H 29/8512; H10H 29/856; H10H 29/882

(57) ABSTRACT

Provided is a display panel. The display panel includes a base substrate, a light-emitting layer, a package layer, and a light conversion layer that are successively stacked. The light conversion layer includes a plurality of light conversion units arranged in an array and a plurality of micro-mirror structures. The plurality of light conversion units include a plurality of first light conversion units, and the plurality of micro-mirror structures include a plurality of first micro-mirror structures surrounding the first light conversion units. Each of the first micro-mirror structures is configured to reflect at least a portion of light from an interior of each of the first light conversion units.

### CROSS-REFERENCE TO RELATED APPLICATION

The present disclosure is a U.S. national stage of international application No. PCT/CN2023/085706, filed on Mar. 31, 2023, the content of which is herein incorporated by reference in its entirety.

### TECHNICAL FIELD

The present disclosure relates to the field of display technologies, and in particular, relates to a display panel, a method for manufacturing the same, and a display device.

### BACKGROUND

Display devices are widely used in such as smartphones, tablet computers, and other electronic devices that are commonly used in daily life. Display panels are important components for display devices.

### SUMMARY

Embodiments of the present disclosure provide a display panel, a method for manufacturing the same, and a display device. The technical solutions are as follows.

According to some embodiments of the present disclosure, a display panel is provided. The display panel includes a base substrate, a light-emitting layer, a package layer, and a light conversion layer that are successively stacked; wherein the light conversion layer includes a plurality of light conversion units arranged in an array and a plurality of micro-mirror structures; wherein the plurality of light conversion units include a plurality of first light conversion units, and the plurality of micro-mirror structures include a plurality of first micro-mirror structures surrounding the first light conversion units, each of the first micro-mirror structures being configured to reflect at least a portion of light from an interior of each of the first light conversion units.

In some embodiments, the plurality of first micro-mirror structures are arranged in a single layer; or the plurality of first micro-mirror structures are arranged in a plurality of layers in a direction perpendicular to a bearing surface of the base substrate.

In some embodiments, an orthographic projection of the micro-mirror structure on a bearing surface of the base substrate is in a circular, hexagonal or octagonal shape, and the plurality of micro-mirror structures each have a curvature to protrude towards a direction away from the base substrate.

In some embodiments, each of the micro-mirror structures includes a reflection portion and a lens portion that are successively stacked, the reflection portion being proximal to the base substrate.

In some embodiments, the reflection portion includes at least one of a hemisphere, a column, a dome, a prism, a cone, or a prism.

In some embodiments, orthographic projections of the plurality of first micro-mirror structures are partially overlapped or not overlapped with an orthographic projection of each of the first light conversion units surrounded by the plurality of first micro-mirror structures on a bearing surface of the base substrate.

In some embodiments, the plurality of light conversion units further include a plurality of second light conversion units and a plurality of third light conversion units; and the plurality of micro-mirror structures further include at least one of: a plurality of second micro-mirror structures, wherein the plurality of second micro-mirror structures surround the second light conversion units, and a number of the first micro-mirror structures surrounding any of the first light conversion units is greater than a number of the second micro-mirror structures surrounding any of the second light conversion units; and a plurality of third micro-mirror structures, wherein the plurality of third micro-mirror structures surround the third light conversion units, and the number of the first micro-mirror structures surrounding any of the first light conversion units is greater than a number of the third micro-mirror structures surrounding any of the third light conversion units.

In some embodiments, each of the first light conversion units includes red light quantum dot light-emitting particles, and each of the second light conversion units includes green light quantum dot light-emitting particles.

In some embodiments, an area of an orthographic projection of each of the first light conversion units on a bearing surface of the base substrate is smaller than an area of an orthographic projection of each of the second light conversion units on the bearing surface of the base substrate.

In some embodiments, each of the first light conversion units and each of the second light conversions unit both further include a plurality of organic nanoparticles, the organic nanoparticles being connected, via organic groups on the organic nanoparticles, to quantum dot light-emitting particles in the light conversion unit in which the organic nanoparticles are disposed.

In some embodiments, each of the light conversion units includes a plurality of scattering particles; wherein each of the scattering particles includes a core structure and a shell structure surrounding the core structure, the shell structure being an unenclosed structure with holes therein.

In some embodiments, a diameter of each of the scattering particles ranges from 10 nm to 300 nm, and a thickness of the shell structure ranges from 10 nm to 20 nm.

In some embodiments, the shell structure is made of metal oxide, nitride, fluoride, or nitrogen oxide.

In some embodiments, the core structure is made of titanium, tantalum, zirconium, niobium, aluminum, silicon, magnesium, iridium, yttrium, ytterbium, indium, tungsten, molybdenum, vanadium, nickel, silver, copper, gold, or an alloy.

In some embodiments, the light conversion layer further includes a first isolation structure, wherein the first isolation structure is disposed between adjacent light conversion units of the plurality of light conversion units, and a refractive index of a material of the first isolation structure is less than a refractive index of each of the light conversion units.

In some embodiments, the display panel includes a color film layer, disposed on a side, distal from the base substrate, of the light conversion layer; wherein the color film layer includes a plurality of color resist blocks and a second isolation structure, the plurality of color resist blocks being in one-to-one correspondence to the plurality of light conversion units; and the second isolation structure is disposed between adjacent color resist blocks of the plurality of color resist blocks, and the first isolation structure and the second isolation structure are formed as a one-piece structure.

In some embodiments, the light conversion layer further includes a reflection structure, the reflection structure being disposed within the first isolation structure and surrounding the light conversion unit.

In some embodiments, in a direction perpendicular to a bearing surface of the base substrate, an absolute value of a difference between a size of the reflection structure and a size of the light conversion unit ranges from 0 to 2.5 μm.

According to some embodiments of the present disclosure, a display panel is provided. The display panel includes, a base substrate, a light emitting layer, a package layer, and a light conversion layer that are successively stacked. The light conversion layer includes a plurality of light conversion units arranged in an array. The plurality of light conversion units include a plurality of scattering particles. The scattering particles include a core structure and a shell structure surrounding the core structure. The shell structure is an unenclosed structure.

In some embodiments, at least a portion of the light conversion units includes a plurality of quantum dot light-emitting particles and a plurality of organic nanoparticles. The organic nanoparticles are connected to the quantum dot light-emitting particles via organic groups disposed on the organic nanoparticles.

In some embodiments, the light conversion layer further includes a first isolation structure. The first isolation structure is disposed between adjacent light conversion units of the plurality of light conversion units. A refractive index of a material of the first isolation structure is less than a refractive index of each of the light conversion units.

In some embodiments, the display panel further includes a color film layer. The color film layer is disposed on a side, distal from the base substrate, of the light conversion layer. The color film layer includes a plurality of color resist blocks and a second isolation structure. The plurality of color resist blocks are in one-to-one correspondence to the plurality of light conversion units. The second isolation structure is disposed between adjacent color resist blocks of the plurality of color resist blocks. The first isolation structure and the second isolation structure are formed as a one-piece structure.

In some embodiments, the light conversion layer further includes a reflection structure. The reflection structure is in the first isolation structure and surround the light conversion unit.

In some embodiments, in a direction perpendicular to a bearing surface of the base substrate, an absolute value of a difference between a size of the reflection structure and a size of the light conversion unit ranges from 0 to 2.5 μm.

According to some embodiments of the present disclosure, a display device is provided. The display device includes a power supply circuit and a display panel, wherein the power supply circuit is configured to supply power to the display panel; and the display panel is the display panel as described above.

According to some embodiments of the present disclosure, a method for manufacturing a display panel is provided. The method includes: providing a base substrate; successively forming a light-emitting layer and a package layer on the base substrate; forming a light conversion layer on the package layer, wherein the light conversion layer includes a plurality of light conversion units arranged in an array and a plurality of micro-mirror structures, the plurality of light conversion units include a plurality of first light conversion units, the plurality of micro-mirror structures include a plurality of first micro-mirror structures surrounding the first light conversion units, and the plurality of first micro-mirror structures are configured to reflect at least a portion of light from an interior of each of the first light conversion units.

In some embodiments, forming the plurality of light conversion units on the package layer includes: forming the plurality of the first light conversion units on the package layer using solution printing, wherein the solution includes an organic solvent, and a plurality of quantum dot light-emitting particles and a plurality of organic nanoparticles dispersed within the organic solvent, and a ratio of a concentration of the organic nanoparticles to a concentration of the quantum dot light-emitting particles ranges from 5% to 30%.

### BRIEF DESCRIPTION OF DRAWINGS

FIG. 1 is a top-view schematic structural diagram of a display panel according to some embodiments of the present disclosure;

FIG. 2 is a schematic diagram of a film layer structure of a display panel according to some embodiments of the present disclosure;

FIG. 3 is a schematic diagram of a film layer structure of another display panel according to some embodiments of the present disclosure;

FIG. 4 is a top-view schematic diagram of a micro-mirror structure according to some embodiments of the present disclosure;

FIG. 5 is a top-view schematic diagram of another micro-mirror structure according to some embodiments of the present disclosure;

FIG. 6 is a schematic diagram of a three-dimensional structure of a micro-mirror structure according to some embodiments of the present disclosure;

FIG. 7 is a side-view schematic diagram of a micro-mirror structure according to some embodiments of the present disclosure;

FIG. 8 is a schematic diagram of a film layer structure of still another display panel according to some embodiments of the present disclosure;

FIG. 9 is a schematic diagram of a film layer structure of yet still another display panel according to some embodiments of the present disclosure;

FIG. 10 is a schematic diagram of a film layer structure of yet still another display panel according to some embodiments of the present disclosure;

FIG. 11 is a schematic structural diagram of a scattering particle according to some embodiments of the present disclosure; and

FIG. 12 is a flowchart of a method for manufacturing a display panel according to some embodiments of the present disclosure.

### REFERENCE NUMERALS AND DENOTATIONS THEREOF

11—Base substrate, 12—Driver circuit layer, 13—First electrode layer;
14—Light-emitting material layer, 15—Second electrode layer 16—Package layer;
2—Light conversion layer;
20—Micro-mirror structure, h—Height of the micro-mirror structure;
201—Reflection portion, 202—Lens portion;
21—Red light conversion unit, 22—Green light conversion unit;
23—Blue light conversion unit, 24—Scattering particle;
241—Core structure, 242—Shell structure;
d1—Diameter of the scattering particle, d2—Diameter of the core structure, d3—Thickness of the shell structure;
25—First isolation structure, 26—Reflection structure;
3—Color film layer, 31—Second isolation structure.

### DETAILED DESCRIPTION

The present disclosure is described in further detail with reference to the accompanying drawings, to clearly present the objects, technical solutions, and advantages of the present disclosure.

The terms used in the detailed description of the present disclosure are merely for interpreting, instead of limiting, the embodiments of the present disclosure. It should be noted that unless otherwise defined, technical or scientific terms used in the embodiments of the present disclosure shall have ordinary meanings understandable by persons of ordinary skill in the art to which the disclosure belongs. The terms “first,” “second,” and the like used in the embodiments of the present disclosure are not intended to indicate any order, quantity, or importance, but are merely used to distinguish the different components. The terms “comprise,” “include,” and derivatives or variations thereof are used to indicate that the element or object preceding the terms covers the element or object following the terms and its equivalents, and shall not be understood as excluding other elements or objects.

In some practices, the display panel includes a base substrate, a light-emitting layer, a package layer, and a light conversion layer that are successively stacked. The light conversion layer includes a plurality of light conversion units arranged in an array, and at least some of the plurality of light conversion units have a low light extraction efficiency.

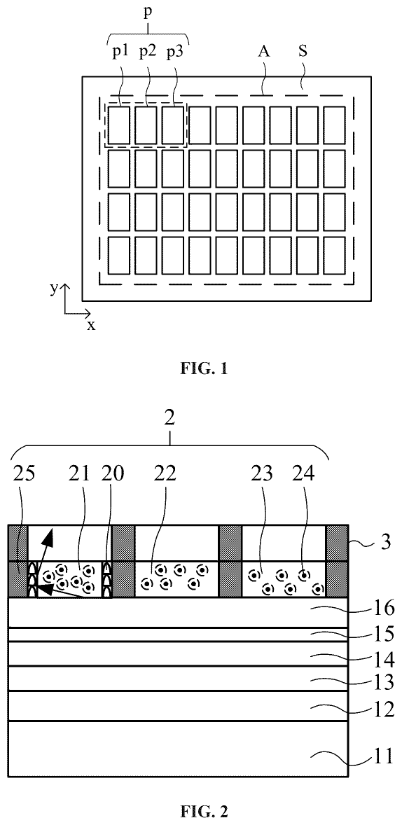

FIG. 1 is a top-view schematic structural diagram of a display panel according to some embodiments of the present disclosure. As illustrated in FIG. 1, the display panel includes a display region A and a peripheral region S. The peripheral region S surrounds the AA region. The display region A displays images, and a plurality of pixels p are provided in the display region A. The peripheral region S does not display images, and a display driver circuit, in some embodiments, a gate driver circuit and a source driver circuit, is provided in the peripheral region S.

The display region A includes the plurality of pixels p arranged in an array along a first direction x and a second direction y. In some embodiments, as illustrated in FIG. 1, each of the pixels p includes three sub-pixels arranged along the first direction x. The three sub-pixels are a first sub-pixel p1, a second sub-pixel p2, and a third sub-pixel p3 that are arranged along the first direction x.

In some embodiments, colors corresponding to the first sub-pixel p1, the second sub-pixel p2, and the third sub-pixel p3 are respectively red, green, and blue. Sub-pixels arranged in a row along the first direction x are referred to as a same row of sub-pixels, and the same row of sub-pixels is connected to a gate line (not illustrated in FIG. 1). Sub-pixels arranged in a column along the second direction y are referred to as a same column of sub-pixels, and the same column of sub-pixels is connected to a data line (not illustrated in FIG. 1).

The number of sub-pixels included in each pixel and the arrangement of sub-pixels in each pixel are not limited herein. In some other embodiments, each pixel p includes four sub-pixels, and the four sub-pixels are organized into two rows. The colors corresponding to the four sub-pixels are red, blue, green, and green. The red sub-pixel and one of the green sub-pixels are arranged alternately in one row, and the blue sub-pixels and another green sub-pixel are arranged alternately in another row.

FIG. 2 is a schematic diagram of a film layer structure of a display panel according to some embodiments of the present disclosure. As illustrated in FIG. 2, the display panel includes a base substrate 11, a driver circuit layer 12, a light-emitting layer, a package layer 16, and a light conversion layer 2 that are successively stacked. The light-emitting layer includes a first electrode layer 13, a light-emitting material layer 14, and a second electrode layer 15 that are successively stacked on the base substrate.

The light conversion layer 2 includes a plurality of light conversion arranged in an array. The plurality of light conversion units are in one-to-one correspondence to the plurality of sub-pixels. That is, each of the sub-pixels includes one of the light conversion units.

In some embodiments of the present disclosure, the plurality of light conversion units include light conversion units corresponding to different colors. In some embodiments, the plurality of light conversion units include a first light conversion unit, a second light conversion unit, and a third light conversion unit. The first light conversion unit, the second light conversion unit, and the third light conversion unit are configured to emit light of different colors, respectively.

The description is given using a scenario where the first light conversion unit is a red light conversion unit for emitting red light, the second light conversion unit is a green light conversion unit for emitting green light, and the third light conversion unit is a blue light conversion unit for emitting blue light.

In some embodiments, the plurality of light conversion units include a red light conversion unit 21, a green light conversion unit 22, and a blue light conversion unit 23. The red light conversion unit 21 includes a plurality of red quantum dot light-emitting particles, and the green light conversion unit 22 includes a plurality of green quantum dot light-emitting particles. The red quantum dot light-emitting particle and the green quantum dot light-emitting particle respectively emit red light and green light, under the excitation of blue light. The blue light conversion unit 23 includes a high transmittance material, in some embodiments, a transparent resin material such as polyimide, polyacrylic acid, and the like.

The light conversion layer 2 further includes a plurality of micro-mirror structures 20. The plurality of micro-mirror structures 20 includes a first micro-mirror structure surrounding the red light conversion unit 21. The plurality of first micro-mirror structures are configured to reflect at least a portion of light from an interior of the red light conversion unit 21.

A refractive index of the material of the micro-mirror structures is less than a refractive index of the light conversion unit. That is, the micro-mirror structure is an optically thinner medium with respect to the light conversion unit. Therefore, the light being incident from the red light conversion unit to an interface of the red light conversion unit and the first micro-mirror structure is equivalent to the light being incident from the optically denser medium to the optically thinner medium. Total reflection occurs when an incident angle satisfies a total reflection condition. The first micro-mirror structure is capable of at least reflecting the light with a large angle within the red light conversion unit. In this way, the light that could not have been directed to a side, distal from the base substrate, of the light conversion layer is reflected to the side, distal from the base substrate, of the light conversion layer, such that the light extraction efficiency is increased, and thus the light extraction efficiency of the red light is improved.

In some embodiments, as illustrated in FIG. 2, in a direction perpendicular to a bearing surface of the base substrate 11, the light conversion layer 2 includes a plurality of layers of first micro-mirror structures. The plurality of layers of micro-mirror structures further increase the light extraction efficiency and improve the light extraction efficiency of the red light. In some embodiments, a transparent material, such as a transparent pixel-defining material, is also present between the plurality of adjacent first micro-mirror structures. The transparent material is filled between the plurality of first micro-mirror structures until a region including the first micro-mirror structures is filled to be flush with the light conversion unit.

In some embodiments, in the direction perpendicular to the bearing surface of the base substrate 11, the light conversion layer 2 includes a layer of the first micro-mirror structure.

The light-emitting layer includes a plurality of light-emitting units arranged in an array, and each of the light-emitting units includes a first electrode in the first electrode layer 13, a light-emitting portion in the light-emitting material layer 14, and a second electrode in the second electrode layer 15. The plurality of light-emitting units are in one-to-one correspondence to the plurality of sub-pixels. That is, each of the sub-pixels includes one of the light-emitting units. For the light conversion unit and the light-emitting unit that are disposed within the same sub-pixel, an orthographic projection of the light conversion unit on the bearing surface of the base substrate 11 is at least partially overlapped with an orthographic projection of the light-emitting unit on the bearing surface of the base substrate 11. In some embodiments, the plurality of light-emitting units emit blue light under the control of the driver circuit layer 12. The blue light, after passing through the red light conversion unit 21, the green light conversion unit 22, and the blue light conversion unit 23, correspondingly generates red, green, and blue light, which respectively correspond to the first sub-pixel p1, the second sub-pixel p2, and the third sub-pixel p3, such that a color display is realized.

In some embodiments, the first electrode layer 13 is an anode layer and the second electrode layer 15 is a cathode layer; alternatively, the first electrode layer 13 is a cathode layer and the second electrode layer 15 is an anode layer.

The driver circuit layer 12 includes a plurality of pixel circuits. Each of the pixel circuits includes electronic devices such as thin film transistors (TFT) and capacitances (C). The TFT includes a switch TFT and a driver TFT. In some embodiments, the pixel circuit is a 2T1C structure including two TFTs (a switch TFT and a driver TFT) and a capacitor; of course, the pixel circuit includes more than two TFTs (a plurality of switch TFTs and a driver TFT) and at least one capacitor. The pixel circuit must include a driver TFT, and the driver TFT is connected to the light-emitting unit.

In the experiment process, it was found that not only blue light excites red quantum dots of red light-emitting particles to emit red light, but green light also excites red light-emitting particles of red quantum dots to emit red light. That is, for a red light conversion unit and an adjacent green light conversion unit, in the case that only the green light conversion unit is controlled to emit light, the red light conversion unit is interfered by the large-angle green light emitted from the adjacent green light conversion unit and is mistakenly excited to emit red light, generating a problem of color crosstalk.

In some embodiments of the present disclosure, as illustrated in FIG. 2, to ameliorate the problem of color crosstalk, an area of an orthographic projection of the red light conversion unit 21 on the bearing surface of the substrate 11 is minimized, and an area of an orthographic projection of the green light conversion unit 22 on the bearing surface of the substrate 11 is similar to an area of an orthographic projection of the blue light conversion unit 23 on the bearing surface of the substrate 11, such that a distance between the red light conversion unit 21 and the green light conversion unit 22, and a distance between the red light conversion unit 21 and the blue light conversion unit 23 are increased, and thus the problem of color crosstalk is improved. Meanwhile, for the light extraction efficiency of the red light conversion unit 21, although the luminance efficiency of the red light is reduced due to the minimum area of the orthographic projection of the red light conversion unit 21 on the bearing surface of the base substrate 11, the light extraction efficiency of the red light is high because of the plurality of first micro-mirror structures arranged around the red light conversion unit 21.

In some embodiments, the light conversion layer 2 further includes a first isolation structure 25. The first isolation structure 25 is in the light conversion layer 2, and an orthographic projection of the first isolation structure 25 on the bearing surface of the base substrate 11 covers orthographic projections of the plurality of micro-mirror structures 20 on the bearing surface of the base substrate 11.

In some embodiments, the first isolation structure 25 is made of a light-absorbing material, such as a black organic material.

In some other embodiments, as illustrated in FIG. 3, FIG. 3 is a schematic diagram of a film layer structure of another display panel according to some embodiments of the present disclosure. In the case that the area of the orthographic projection of the red light conversion unit 21 on the bearing surface of the base substrate 11 is not reduced, the distance between the red light conversion unit 21 and the green light conversion unit 22 and the distance between the red light conversion unit 21 and the blue light conversion unit 23 are increased, and the plurality of micro-mirror structures 20 are arranged around the red light conversion unit 21, such that the light extraction efficiency of the red light of the display panel is further improved.

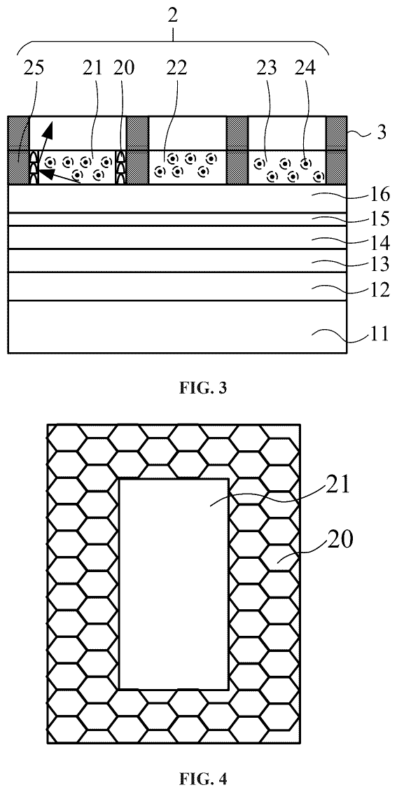

FIG. 4 is a top-view schematic diagram of a micro-mirror structure according to some embodiments of the present disclosure. FIG. 5 is a top-view schematic diagram of another micro-mirror structure according to some embodiments of the present disclosure. As illustrated in FIG. 4, the orthographic projection of the micro-mirror structure 20 on the bearing surface of the base substrate 11 is in a hexagonal shape; or, as illustrated in FIG. 5, the orthographic projection of the micro-mirror structure 20 on the bearing surface of the base substrate 11 is in an octagonal shape; or the orthographic projection of the micro-mirror structure 20 on the bearing surface of the base substrate 11 is in a circular shape. The plurality of first micro-mirror structures around the red light conversion unit 21 are close-packed as far as possible. That is, gaps between the plurality of micro-mirror structures are minimized as much as possible. The close-packed arrangement allows as many first micro-mirror structures as possible to be placed, such that the light extraction efficiency is improved as much as possible.

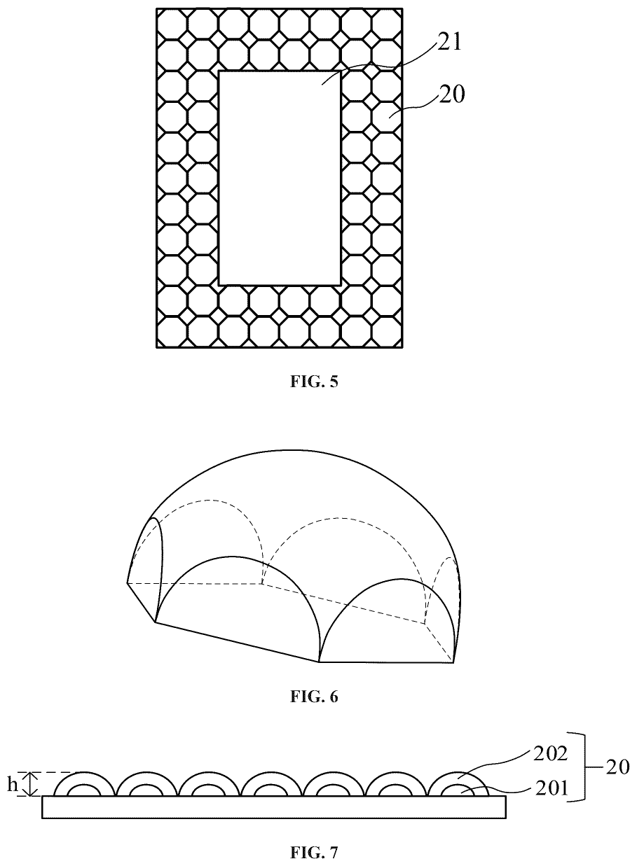

FIG. 6 is a schematic diagram of a three-dimensional structure of a micro-mirror structure according to some embodiments of the present disclosure. As illustrated in FIG. 6, the description is given using a scenario where the orthographic projection of the micro-mirror structure on the bearing surface of the base substrate 11 is in a hexagonal shape as an example, the micro-mirror structure 20 has a curved top surface, and six side surfaces perpendicular to the bearing surface of the base substrate 11. That is, the micro-mirror structure 20 has a curvature to protrude towards a direction away from the base substrate 11.

For the micro-mirror structures of different shapes, a hemispherical micro-mirror structure has the best light extraction effect, and the orthographic projection of the hemispherical micro-mirror structure on the bearing surface of the base substrate 11 is in a circular shape. However, a filling rate is lower in the case that the plurality of hemispherical micro-mirror structures are close-packed. For the micro-mirror structure having a rectangular orthographic projection on the bearing surface of the substrate 11, the filling rate is high in the case that the plurality of micro-mirror structures are close-packed, but the light extraction efficiency is low. Compared to the above two micro-mirror structures, the micro-mirror structure with a hexagonal or octagonal orthographic projection is more similar to the hemispherical micro-mirror structure, and has a higher light extraction efficiency. At the same time, the orthographic projection of hexagonal or octagonal shape achieves a high filling rate when the plurality of micro-mirror structures are close-packed, and thus the red light efficiency is further improved. Herein, the filling rate is the rate of the sum of the areas of the orthographic projections of the plurality of micro-mirror structures on the bearing surface of the base substrate 11 to a total area of a region in which the micro-mirror structures are provided, at a top-view angle of FIG. 4 or FIG. 5. Thus, the smaller the gap between the micro-mirror structures, the greater the fill rate.

Considering the two factors of the shape of the micro-mirror structure and the filling rate together, it is selected that the orthographic projection on the bearing surface of the base substrate 11 is in a hexagonal shape and the adjacent hexagons share the same side to improve the light extraction efficiency.

FIG. 7 is a side-view schematic diagram of a micro-mirror structure according to some embodiments of the present disclosure, as illustrated in FIG. 7, the micro-mirror structure 20 includes a reflection portion 201 and a lens portion 202 that are successively stacked. The reflection portion 201 is proximal to the base substrate 11. The reflection portion 201 is capable of reflecting light with any angle not just a large angle, and thus light extraction is further increased. In some embodiments, the reflection portion 201 is made of a metallic material, such as copper, silver, aluminum, and other materials. In some embodiments, the lens portion 202 is made of glass.

In some embodiments, the reflection portion 201 is in the shape of a hemisphere (as illustrated in FIG. 7), a column, a dome, a prism, a cone, or a prism. All of the reflection portions 201 of these shapes achieve the purpose of reflecting the light back to the region of the red light conversion unit.

In some embodiments, as illustrated in FIG. 7, a thickness h of the micro-mirror structure 20 ranges from 1 m to 3 μm.

In some embodiments of the present disclosure, the plurality of micro-mirror structures 20 further include at least one type of a plurality of second micro-mirror structures surrounding the green light conversion unit 22 and a plurality of third micro-mirror structures surrounding the blue light conversion unit 23. For any red light conversion unit 21 and any green light conversion unit 22, the number of second micro-mirror structures surrounding the green light conversion unit 22 is less than the number of first micro-mirror structures surrounding the red light conversion unit 21. For any red light conversion unit 21 and any blue light conversion unit 23, the number of third micro-mirror structures surrounding the blue light conversion unit 23 is less than the number of first micro-mirror structures surrounding the red light conversion unit 21. By providing a small number of micro-mirror structures surrounding the blue light conversion unit and the green light conversion unit, the color balance is achieved.

In some embodiments, the plurality of second micro-mirror structures are provided around the green light conversion unit 22, and the plurality of third micro-mirror structures are provided around the green light conversion unit 22. Compared to the plurality of first micro-mirror structures, as illustrated in FIG. 4 or FIG. 5, in a direction parallel to the base substrate, the plurality of first micro-mirror structures 20 surrounding one of the red light conversion units are approximately divided into a plurality of circles; using the plurality of second micro-mirror structures surrounding one of the green light conversion units as an example, in the direction parallel to the base substrate, one of the green light conversion units has only one circle of the second micro-mirror structures.

In some embodiments of the present disclosure, the plurality of micro-mirror structures 20 include only the plurality of first micro-mirror structures; alternatively, the plurality of micro-mirror structures 20 include only the plurality of first micro-mirror structures and the plurality of second micro-mirror structures; alternatively, the plurality of micro-mirror structures 20 include only the plurality of first micro-mirror structures and the plurality of third micro-mirror structures; alternatively, the plurality of micro-mirror structures 20 include the plurality of first micro-mirror structures, the plurality of second micro-mirror structures, and the plurality of third micro-mirror structures. For a light conversion unit, the more the number of surrounding micro-mirror structures, the higher the light extraction efficiency of the light conversion unit. For consideration of the color balance, different numbers of second micro-mirror structures and third micro-mirror structures are provided around the green light conversion unit or the blue light conversion unit.

In some embodiments, the plurality of micro-mirror structures 20 surrounding the same light conversion unit have different sizes and different shapes.

In some embodiments, orthographic projections of the plurality of first micro-mirror structures are overlapped with the orthographic projection on the bearing surface of the base substrate 11 of the first light conversion unit being surrounded. In some embodiments, an edge of the first light conversion unit overlaps a portion of the first micro-mirror structures.

In other embodiments, orthographic projections of the plurality of first micro-mirror structures are not overlapped with the orthographic projection on the bearing surface of the base substrate 11 of the first light conversion unit being surrounded, such as the structure illustrated in FIG. 3.

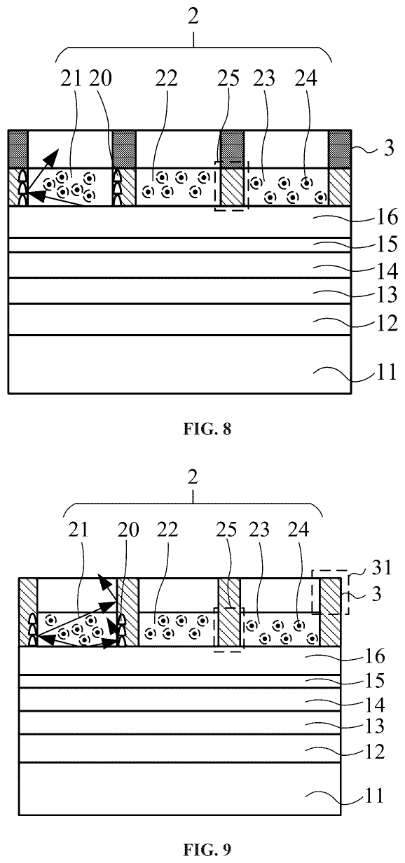

FIG. 8 is a schematic diagram of a film layer structure of another display panel according to some embodiments of the present disclosure. As illustrated in FIG. 8, to improve the problem of color crosstalk while increasing the light extraction, on the basis of providing the plurality of layers of micro-mirror structures 20, the first isolation structure 25 is in the light conversion layer 2 and the first isolation structure 25 is made of a material with a refractive index that is less than the refractive index of the material of the light conversion unit. The refractive index of the material of the first isolation structure 25 is less than the refractive index of the light conversion unit. That is, the material of the first isolation structure 25 is an optically thinner medium with respect to the light conversion unit, and the light conversion unit is an optically denser medium with respect to the material of the first isolation structure 25. Therefore, light being incident to an interface of the light conversion unit and the first isolation structure 25 is equivalent to light being incident from the optically denser medium to the optically thinner medium, and in the case that the incident angle satisfies the total reflection condition, the total reflection occurs, and the light returns to an interior of the light conversion unit from the interface of the light conversion unit and the first isolation structure 25. Thereby, the total reflection of light is realized and the problem of color crosstalk is improved without the need to arrange an optical structure at the interface of the light conversion unit and the first isolation structure 25. At the same time, compared to a light-absorbing structure, which absorbs the large-angle light generated within the respective light conversion units and thus leads to the problem of low optical power, the light extraction is increased due to the fact that the first isolation structure 25 fully reflects the large-angle light within the respective light conversion units back to the corresponding region.

In some embodiments, in the direction perpendicular to the bearing surface of the base substrate 11, the light conversion layer 2 includes a layer of first micro-mirror structure and a low refractive index material. The low refractive index material fills in the gaps of the plurality of first micro-mirror structures until the region including the first micro-mirror structures is filled to be flush with the light conversion unit.

As illustrated in FIG. 8, the display panel further includes a color film layer 3. The color film layer 3 is disposed on a side, distal from the base substrate 11, of the light conversion layer 2. The color film layer 3 includes a plurality of color resist blocks. The plurality of color resist blocks are in one-to-one correspondence to the plurality of light conversion units. The plurality of color resist blocks are separated from each other by a light-absorbing material such as a black matrix.

FIG. 9 is a schematic diagram of a film layer structure of another display panel according to some embodiments of the present disclosure. Compared to the embodiments illustrated in FIG. 8, in the embodiments illustrated in FIG. 9, the display panel further includes a color film layer 3, the color film layer 3 being disposed on a side, distal from the base substrate 11, of the light conversion layer 2. The color film layer 3 includes a plurality of color resist blocks and a second isolation structure 31. The plurality of color resist blocks are in one-to-one correspondence to the plurality of light conversion units. The second isolation structure 31 is disposed between adjacent color resist blocks, and the first isolation structure 25 and the second isolation structure 31 are formed as a one-piece structure. The one-piece structure herein means that the first isolation structure 25 and the second isolation structure are two parts of an integral structure, and the first isolation structure 25 and the second isolation structure are made of the same material. The connected first isolation structure 25 and the second isolation structure 31 further improve the color crosstalk, and at the same time increase the light extraction by always reflecting, in a direction from close to the light conversion unit to away from the light conversion unit, the large-angle light back into the corresponding light conversion unit and color resist region until the light exits out of the color film layer.

In some embodiments, the first isolation structure 25 and the second isolation structure 31 are made of organic materials, such as polyimide, polymethylmethacrylate, and the like.

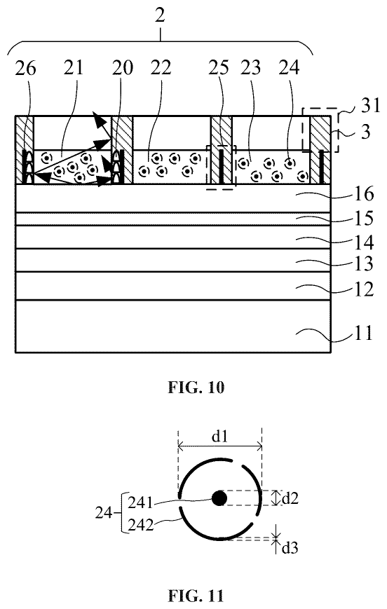

FIG. 10 is a schematic diagram of a film layer structure of another display panel according to some embodiments of the present disclosure. As illustrated in FIG. 10, compared to the display panel illustrated in FIG. 9, the light conversion layer 2 further includes a reflection structure 26. The reflection structure 26 is in the first isolation structure 25 and surrounds the light conversion unit. The reflection structure 26 further improves the phenomenon of color crosstalk between adjacent two light conversion units, and the reflection structure 26 also provides a better total reflection of the large-angle light.

In some embodiments, as illustrated in FIG. 10, a size of the reflection structure 26 is the same as a size of the light conversion unit in the direction perpendicular to the bearing surface of the base substrate.

In some other embodiments, a height of the reflection structure 26 is also slightly higher or slightly lower than a height of the light conversion unit. In some embodiments, an absolute value of a height difference between the reflection structure 26 and the light conversion unit ranges from 0 to 2.5 μm.

In some embodiments, the reflection structure 26 is made of a metallic material, such as copper, silver, aluminum, and other metallic materials.

It should be noted that the reflection structure 26 is provided in the display panel illustrated in FIG. 8.

In some embodiments, the light conversion layer 2 is prepared directly on the package layer 16.

In some other embodiments, the display panel further includes a first adhesive layer. The first adhesive layer is disposed between the color film layer 3 and the light conversion layer 2. The first adhesive layer is made of an organic adhesive material to adhere the color film layer and to the light conversion layer.

In some embodiments, the display panel further includes a second adhesive layer. The second adhesive layer is disposed between the light conversion layer 2 and the package layer 16. The second adhesive layer is made of an organic adhesive material to adhere the light conversion to the package layer.

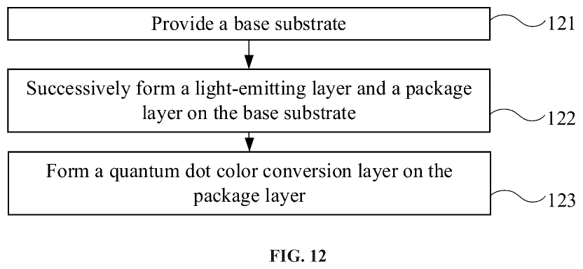

In some embodiments of the present disclosure, the light conversion unit includes a plurality of scattering particles, and the scattering particles are configured to increase the optical path of the light emitted from the light-emitting unit and increase the absorption of the blue light by the light conversion unit. FIG. 11 is a schematic structural diagram of a scattering particle according to some embodiments of the present disclosure. As illustrated in FIG. 11, the scattering particle 24 includes a core structure 241 and a shell structure 242 surrounding the core structure 241. The shell structure 242 is an unenclosed structure with holes therein.

The light emitted from the light-emitting layer is reflected between the core structure 241 and the shell structure 242 of the scattering particle 24 after entering the light conversion unit, and the light path is increased, which increases the absorption of the light emitted from the light-emitting layer by the light conversion unit, and improves the conversion efficiency of the light conversion layer, such that the light extraction rate of the light conversion unit including the red light conversion unit and the green light conversion unit is further improved.

In some embodiments of the present disclosure, although the blue light conversion unit does not include the quantum dot light-emitting particles, it still includes the scattering particles. In this way, the viewing angle of the product is improved, the uniformity of the doping of the light conversion layer is increased, and the manufacturing process is simplified.

In some embodiments, as illustrated in FIG. 11, a diameter d1 of the scattering particle 24 ranges from 10 nm to 300 nm, a diameter d2 of the core structure 241 ranges from 2 nm to 8 nm, and a thickness d3 of the shell structure 242 ranges from 10 nm to 20 nm. By defining the size of the scattering particle to be within the above range, on the premise of satisfying the stable manufacturing as much as possible, the scattering particles will not be too small to agglomerate easily, and will not be too large to cause poor scattering effect.

In some embodiments, the shell structure 242 is made of metal oxide, nitride, fluoride, or nitrogen oxide.

The core structure 241 is made of titanium, tantalum, zirconium, niobium, aluminum, silicon, magnesium, iridium, yttrium, ytterbium, indium, tungsten, molybdenum, vanadium, nickel, silver, copper, gold, or an alloy. The material, such as metal oxide, nitride, fluoride, or nitrogen oxide, is etched by organic acidic or alkaline solvents to form an unenclosed structure with holes therein. The metal oxide, nitride, fluoride, or nitrogen oxide, and materials such as titanium, tantalum, and alloys, are able to reflect light well.

In some embodiments, the display panel according to the present disclosure includes the scattering particles and does not include the micro-mirror structure 20, the first isolation structure 25, the second isolation structure 31, and the reflection structure 26 as described above.

In some other embodiments, the display panel according to the present disclosure includes the scattering particles and the plurality of micro-mirror structures 20 (as illustrated in FIG. 2 or FIG. 3).

In some other embodiments, the display panel according to the present disclosure includes the scattering particles and the first isolation structure 25 (as illustrated in FIG. 8); or the display panel according to the present disclosure includes the scattering particles, the first isolation structure 25, and the second isolation structure 31 (as illustrated in FIG. 9); or the display panel according to the present disclosure includes the scattering particles, the first isolation structure 25, the second isolation structure 31, and the reflection structure 26 (as illustrated in FIG. 10).

In some other embodiments, the display panel according to the present disclosure includes the scattering particles, the micro-mirror structure 20, and the first isolation structure 25 (as illustrated in FIG. 8); or the display panel according to the present disclosure includes the scattering particles, the micro-mirror structure 20, the first isolation structure 25, and the second isolation structure 31 (as illustrated in FIG. 9); or the display panel according to the present disclosure includes the scattering particles, the micro-mirror structure 20, the first isolation structure 25, the second isolation structure 31, and the reflection structure 26 (as illustrated in FIG. 10).

In some embodiments of the present disclosure, the red light conversion unit and the green light conversion unit include a plurality of organic nanoparticles. The organic nanoparticles are connected, via organic groups on the organic nanoparticles, to the quantum dot light-emitting particles in the light conversion unit in which they are disposed.

The higher the concentration of the quantum dot light-emitting particles, the higher the conversion rate of light. However, quenching occurs in the case that the concentration of the quantum dot light-emitting particles is too high. After the organic nanoparticles are added, the organic nanoparticles surround the quantum dot light-emitting particles, and thus the quantum dot light-emitting particles are less likely to agglomerate. In this way, the problem of agglomeration and quenching of the quantum dot light-emitting particles after too many of the quantum dot light-emitting particles are added, such that the maximum addition concentration of the quantum dot light-emitting particles is improved, and thus the luminance of the product is improved.

In some embodiments, the quantum dot light-emitting particle is made of at least one compound among CdS, CdSe, CdTe, ZnS, ZnSe, ZnTe, HgS, HgTe, GaN, GaAs, InP, and InAs.

In some embodiments, the organic nanoparticle has the following structural formula.

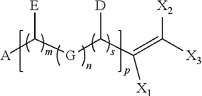

The organic group A on the organic nanoparticle and used to connect to the quantum dot light-emitting particle includes any one of NC—, HOOC—, HRN—, O═P(R)₂—, POOOH—, RS—, and RSS—. The R group includes any one of a hydrogen atom, a saturated carbon-chain with the number of carbon atoms from 1 to 10, and an unsaturated carbon-chain with the number of carbon atoms from 1 to 10.

Any of the X₁ group, the X₂ group, and the X₃ group includes any one of a hydrogen atom, an aryl group, a phenyl group, a halogen, —CH₃, —(CH₂)a-CH₃, —COOH, —COOCH₃, and —CH═CH₂, wherein a is an integer greater than or equal to one.

The E group includes any one of a hydrogen atom, a halogen, a hydroxyl group, a carboxyl group, a carboxylic acid, an ester, a mercapto group, an amine group, a formyl group, —SO₂NH₂, —NHNH₂, a saturated carbon-chain with the number of carbon atoms from 1 to 30, and an unsaturated carbon-chain with the number of carbon atoms from 1 to 10.

The D group includes any one of a hydrogen atom, a halogen, a hydroxyl group, a carboxyl group, a carboxylic acid, an ester, a mercapto group, an amine group, a formyl group, —SO₂NH₂, —NHNH₂, a saturated carbon-chain with the number of carbon atoms from 1 to 30, and an unsaturated carbon-chain with the number of carbon atoms from 1 to 10.

The G group includes any one of —CH₂—, —C═C—, —C≡C—, —COO—, —CONH—, —CO—, —O—, —OCONH, —NH—, —S, —COS, —CH═N—, —NHCONH—, —NHCSNH—, —NHNH—, a benzene ring, cyclohexane, cyclopentane, thiophene, pyridine, pyrrole, imidazole, aniline, furan, and carbazole; wherein m is a natural number, and 0≤m≤30; n is a natural number, and 0≤n≤30; s is a natural number, and 0≤s≤30; (m+n+s)≠0; and p is a positive integer, and 1≤(m+n+s)≤30.

Some embodiments of the present disclosure also provide a display panel that includes a base substrate, a light-emitting layer, a package layer, and a light conversion layer that are successively stacked. The light conversion layer includes a plurality of light conversion units arranged in an array and a first isolation structure 25 as described above. Adjacent two of the light conversion units are separated by the first isolation structure 25. The display panel does not include the micro-mirror structure 20 described above.

In some embodiments, the display panel further includes a color film layer disposed on a side, distal from the base substrate, of the light conversion layer. The color film layer includes a plurality of color resist blocks and the second isolation structure 31 described above. The plurality of color resist blocks are in one-to-one correspondence to the plurality of light conversion units. Adjacent two of the color resist blocks are separated from each other by the second isolation structure 31.

In some embodiments, the display panel further includes the reflection structure 26 described above. The reflection structure 26 is in the first isolation structure 25 and surrounds the light conversion units.

Some embodiments of the present disclosure also provide a method for manufacturing a display panel. FIG. 12 is a flowchart of a method for manufacturing a display panel according to some embodiments of the present disclosure. The method is applicable to manufacturing any of the display panels described above. As illustrated in FIG. 12, the method includes the following steps.

In step 121, a base substrate is provided.

In step 122, a light-emitting layer and a package layer are successively formed on the base substrate.

In step 123, a light conversion layer is formed on the package layer. The light conversion layer includes a plurality of light conversion units arranged in an array and a plurality of micro-mirror structures. The plurality of light conversion units include a plurality of first light conversion units. The plurality of micro-mirror structures include a plurality of first micro-mirror structures surrounding the first light conversion units. The plurality of first micro-mirror structures are configured to reflect at least a portion of the light from an interior of the first light conversion unit.

In some embodiments, in step 123, forming the light conversion layer on the package layer includes forming the plurality of micro-mirror structures first, and then forming the plurality of light conversion units.

In some embodiments, in step 123, the plurality of light conversion units are formed by forming the plurality of first light conversion units on the package layer using solution printing.

In some embodiments, the solution includes an organic solvent, a plurality of quantum dot light-emitting particles and a plurality of organic nanoparticles that are dispersed within the organic solvent. The organic solvent allows the plurality of quantum dot light-emitting particles and the plurality of organic nanoparticles to be uniformly dispersed. The quantum dot light-emitting particles emit another color of light by receiving excitation of the light emitted from the light-emitting layer. The higher the concentration of the quantum dot light-emitting particles, the higher the light extraction efficiency of the first light conversion unit. However, in the case that the concentration of the quantum dot light-emitting particles is too high, a phenomenon of agglomeration occurs, and quenching is likely to occur. By adding the organic nanoparticles, the organic nanoparticles are made to surround the quantum dot light-emitting particles, such that the quantum dot light-emitting particles are less likely to be agglomerated.

In some embodiments, a ratio of the concentration of the organic nanoparticles to the concentration of the quantum dot light-emitting particles ranges from 5% to 30%. The organic nanoparticles, within this concentration range, will not be so low that they fail to improve the agglomeration and quenching of quantum dot-emitting particles, and will not be so high that they interfere with normal light conversion of the quantum dot light-emitting particles.

Similarly, the second light conversion unit described above is prepared in the same way as the first light conversion unit.

In some embodiments, the light conversion unit is formed using a deposition method.

In some embodiments, in step 123, the light conversion unit is acquired by forming a first isolation structure using the following method.

In step 1, a thin film is formed on the package layer.

In step 2, the first isolation structure is formed by removing a film material in a region in which the light conversion unit is to be formed using laser perforation. A refractive index of the material of the first isolation structure is less than a refractive index of the material of the light conversion unit.

In some other embodiments, in step 123, the light conversion unit is acquired by forming a first isolation structure, a plurality of micro-mirror structures, and a plurality of reflection structures using the following method.

In step 1, the plurality of reflection structures are formed on the package layer by deposition, and the plurality of micro-mirror structures are formed.

In step 2, a thin film covering the plurality of reflection structures and the plurality of micro-mirror structures is formed;

In step 3, the first isolation structure is formed by removing a thin film material in the region where the light conversion unit is to be formed using laser perforation to form the first isolation structure. A refractive index of the material of the first isolation structure is less than a refractive index of the material of the light conversion unit, and the first isolation structure covers the micro-mirror structures and the reflection structures.

Some embodiments of the present disclosure provide a display device that includes the display panel described above and a power supply circuit. The power supply circuit is configured to supply power to the display panel.

In some embodiments, the display device according to some embodiments of the present disclosure is a cell phone, a tablet computer, a television, a monitor, a laptop computer, a digital photo frame, a navigator, or any other product or component having a display function.

The display device has the same effect as the display panel described above, which is not repeated herein.

Some embodiments of the present disclosure also provide a display substrate that includes a light conversion layer, a color film layer, and a transparent substrate that are successively stacked. The light conversion layer includes a plurality of light conversion units arranged in an array and a plurality of micro-mirror structures. The plurality of light conversion units include a plurality of red light conversion units, and the plurality of micro-mirror structures include a plurality of first micro-mirror structures surrounding the red light conversion units. The plurality of first micro-mirror structures are configured to reflect at least a portion of light from an interior of the red light conversion unit. The color film layer includes a plurality of color resist blocks. The plurality of color resist blocks are in one-to-one correspondence to the plurality of light conversion units. For other structures of the light conversion layer, reference is made to the preceding embodiments, which is not repeated herein.

Some embodiments of the present disclosure also provide a display substrate that includes a light conversion layer, a color film layer, and a transparent substrate that are successively stacked. The light conversion layer includes a plurality of light conversion units arranged in an array. The plurality of light conversion units include a plurality of scattering particles. The scattering particle includes a core structure and a shell structure surrounding the core structure. The shell structure is an unenclosed structure with holes therein. The color film layer includes a plurality of color resist blocks. The plurality of color resist blocks are in one-to-one correspondence to the plurality of light conversion units. For other structures of the light conversion layer, reference is made to the preceding embodiments, which is not repeated herein.

The technical solutions according to the embodiments of the present disclosure achieve at least the following beneficial effects.

By providing the plurality of first micro-mirror structures around the first light conversion units, the large-angle light emitted from the first light conversion unit is reflected back to the first light conversion unit, such that the light extraction efficiency of the light corresponding to the first light conversion unit is improved.

By adding the plurality of scattering particles to the light conversion unit, wherein the scattering particle includes the core structure and the shell structure with holes, the light incident from the light-emitting layer to the light conversion unit is incident to the interior of the scattering particle through the holes and reflected multiple times between the core structure and the shell structure of the scattering particle. In this way, the light path is increased, and the absorption of the light emitted from the light-emitting layer by the light conversion unit is increased, such that the light conversion unit is excited to generate more light of corresponding colors, and thus the conversion efficiency of the light conversion layer is improved. That is, the light extraction efficiency of the light conversion unit is improved.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A display panel, comprising: a base substrate, a light-emitting layer, a package layer, and a light conversion layer that are successively stacked;
wherein the light conversion layer comprises a plurality of light conversion units arranged in an array and a plurality of micro-mirror structures; wherein the plurality of light conversion units comprise a plurality of first light conversion units, and the plurality of micro-mirror structures comprise a plurality of first micro-mirror structures surrounding the first light conversion units, each of the first micro-mirror structures being configured to reflect at least a portion of light from an interior of each of the first light conversion units.

2. The display panel according to claim 1, wherein the plurality of first micro-mirror structures are arranged in a single layer; or the plurality of first micro-mirror structures are arranged in a plurality of layers in a direction perpendicular to a bearing surface of the base substrate.

3. The display panel according to claim 1, wherein an orthographic projection of the micro-mirror structure on a bearing surface of the base substrate is in a circular, hexagonal or octagonal shape, and the plurality of micro-mirror structures each have a curvature to protrude towards a direction away from the base substrate.

4. The display panel according to claim 1, wherein each of the micro-mirror structures comprises a reflection portion and a lens portion that are successively stacked, the reflection portion being proximal to the base substrate.

5. The display panel according to claim 4, wherein the reflection portion comprises at least one of a hemisphere, a column, a dome, a prism, a cone, or a prism.

6. The display panel according to claim 1, wherein orthographic projections of the plurality of first micro-mirror structures are partially overlapped or not overlapped with an orthographic projection of each of the first light conversion units surrounded by the plurality of first micro-mirror structures on a bearing surface of the base substrate.

7. The display panel according to claim 1, wherein
the plurality of light conversion units further comprise a plurality of second light conversion units and a plurality of third light conversion units; and
the plurality of micro-mirror structures further comprise at least one of:
a plurality of second micro-mirror structures, wherein the plurality of second micro-mirror structures surround the second light conversion units, and a number of the first micro-mirror structures surrounding any of the first light conversion units is greater than a number of the second micro-mirror structures surrounding any of the second light conversion units; and
a plurality of third micro-mirror structures, wherein the plurality of third micro-mirror structures surround the third light conversion units, and the number of the first micro-mirror structures surrounding any of the first light conversion units is greater than a number of the third micro-mirror structures surrounding any of the third light conversion units.

8. The display panel according to claim 7, wherein each of the first light conversion units comprises red light quantum dot light-emitting particles, and each of the second light conversion units comprises green light quantum dot light-emitting particles.

9. The display panel according to claim 8, wherein an area of an orthographic projection of each of the first light conversion units on a bearing surface of the base substrate is smaller than an area of an orthographic projection of each of the second light conversion units on the bearing surface of the base substrate.

10. The display panel according to claim 8, wherein each of the first light conversion units and each of the second light conversion units both further comprise a plurality of organic nanoparticles, the organic nanoparticles being connected, via organic groups on the organic nanoparticles, to quantum dot light-emitting particles in the light conversion unit in which the organic nanoparticles are disposed.

11. The display panel according to claim 1, wherein each of the light conversion units comprises a plurality of scattering particles;
wherein each of the scattering particles comprises a core structure and a shell structure surrounding the core structure, the shell structure being an unenclosed structure with holes therein.

12. The display panel according to claim 11, wherein a diameter of each of the scattering particles ranges from 10 nm to 300 nm, and a thickness of the shell structure ranges from 10 nm to 20 nm.

13. The display panel according to claim 11, wherein
the shell structure is made of metal oxide, nitride, fluoride, or nitrogen oxide; and
the core structure is made of titanium, tantalum, zirconium, niobium, aluminum, silicon, magnesium, iridium, yttrium, ytterbium, indium, tungsten, molybdenum, vanadium, nickel, silver, copper, gold, or an alloy.

14. The display panel according to claim 1, wherein the light conversion layer further comprises a first isolation structure, wherein the first isolation structure is disposed between adjacent light conversion units of the plurality of light conversion units, and a refractive index of a material of the first isolation structure is less than a refractive index of each of the light conversion units.

15. The display panel according to claim 14, comprising a color film layer, disposed on a side, distal from the base substrate, of the light conversion layer; wherein
the color film layer comprises a plurality of color resist blocks and a second isolation structure, the plurality of color resist blocks being in one-to-one correspondence to the plurality of light conversion units; and
the second isolation structure is disposed between adjacent color resist blocks of the plurality of color resist blocks, and the first isolation structure and the second isolation structure are formed as a one-piece structure.

16. The display panel according to claim 14, wherein the light conversion layer further comprises a reflection structure, the reflection structure being disposed within the first isolation structure and surrounding the light conversion unit.

17. The display panel according to claim 16, wherein in a direction perpendicular to a bearing surface of the base substrate, an absolute value of a difference between a size of the reflection structure and a size of the light conversion unit ranges from 0 to 2.5 μm.

18. A display device, comprising: a power supply circuit and a display panel, wherein
the power supply circuit is configured to supply power to the display panel; and
the display panel comprises: a base substrate, a light-emitting layer, a package layer, and a light conversion layer that are successively stacked;
wherein the light conversion layer comprises a plurality of light conversion units arranged in an array and a plurality of micro-mirror structures: wherein the plurality of light conversion units comprise a plurality of first light conversion units, and the plurality of micro-mirror structures comprise a plurality of first micro-mirror structures surrounding the first light conversion units, each of the first micro-mirror structures being configured to reflect at least a portion of light from an interior of each of the first light conversion units.

19. A method for manufacturing a display panel, comprising:
providing a base substrate;
successively forming a light-emitting layer and a package layer on the base substrate;
forming a light conversion layer on the package layer, wherein the light conversion layer comprises a plurality of light conversion units arranged in an array and a plurality of micro-mirror structures, the plurality of light conversion units comprise a plurality of first light conversion units, the plurality of micro-mirror structures comprise a plurality of first micro-mirror structures surrounding the first light conversion units, and the plurality of first micro-mirror structures are configured to reflect at least a portion of light from an interior of each of the first light conversion units.

20. The method for manufacturing the display panel according to claim 19, wherein forming the plurality of light conversion units on the package layer comprises:
forming the plurality of the first light conversion units on the package layer using solution printing, wherein the solution comprises an organic solvent, and a plurality of quantum dot light-emitting particles and a plurality of organic nanoparticles dispersed within the organic solvent, and a ratio of a concentration of the organic nanoparticles to a concentration of the quantum dot light-emitting particles ranges from 5% to 30%.
